(19) United States
(12) Patent Application Publication
(10) Pub. No.: US 2021/0159448 A1
(43) Pub. Date: May 27, 2021

(54) PACKAGING METHOD FOR DISPLAY PANEL, DISPLAY DEVICE AND MANUFACTURING METHOD THEREOF

(71) Applicant: BOE TECHNOLOGY GROUP CO., LTD., Beijing (CN)

(72) Inventor: Donghui YU, Beijing (CN)

(21) Appl. No.: 16/610,695

(22) PCT Filed: Apr. 4, 2019
(86) PCT No.: PCT/CN2019/081417

§ 371 Date: Nov. 4, 2019

(30) Foreign Application Priority Data
Apr. 24, 2018 (CN) 201810374174.2

(51) Int. Cl. H01L 51/52; H01L 51/56

(52) U.S. Cl. CPC H01L 51/5253; H01L 51/56

(57) ABSTRACT

A method for packaging a display panel, a display device, and a manufacturing method thereof are proposed. The method includes providing a substrate, the substrate including a display region and a peripheral region surrounding the display region, the display region including a light emitting element, forming a package defining wall in the peripheral region, the package defining wall surrounding the display region and having a gap with the display region, forming an organic encapsulation layer within a region defined by the package defining wall, the organic encapsulation layer covering the light emitting element and the gap, and peeling off the package defining wall.

### RELATED APPLICATIONS

The present application is a 35 U.S.C. 371 national stage application of a PCT International Application No. PCT/CN2019/081417, filed on Apr. 4, 2019, which claims the benefit of Chinese Patent Application No. 201810374174.2, filed on Apr. 24, 2018, the entire disclosure of which is incorporated herein by reference.

### TECHNICAL FIELD

The present disclosure relates to the field of electronic component manufacture technologies. Specifically, the present disclosure relates to a packaging method for a display panel, a display device, and a manufacturing method thereof.

### BACKGROUND

Organic light emitting diodes (OLEDs) are display lighting technologies that have been developed in recent years. Especially in the display industry, OLED displays are considered to have broad application prospects due to their advantages such as fast response, high contrast, flexibility, and the like. However, since OLED devices are apt to be corroded and damaged under the effect of water vapor and oxygen, it is particularly important to package the OLED devices properly.

### SUMMARY

In a first aspect of the disclosure, a packaging method of a display panel is proposed. According to an embodiment of the disclosure, the method comprises: providing a substrate, the substrate comprising a display region and a peripheral region surrounding the display region, the display region comprising a light emitting element; forming a package defining wall in the peripheral region, the package defining wall surrounding the display region and having a gap with the display region; forming an organic encapsulation layer within a region defined by the package defining wall, the organic encapsulation layer covering the light emitting element and the gap, and peeling off the package defining wall.

According to an embodiment of the disclosure, a cross section of the package defining wall in a direction perpendicular to the substrate is in a shape of a square or a trapezoid.

According to an embodiment of the disclosure, a distance from a side surface of the organic encapsulation layer away from the light emitting element to a side surface of the light emitting element is not greater than 50 microns.

According to an embodiment of the disclosure, a width of the package defining wall in a horizontal direction ranges from 10 to 100 microns.

According to an embodiment of the disclosure, the package defining wall is peeled off by a thermal peeling process, and a temperature during the thermal peeling process is not higher than 100 degrees Celsius.

According to an embodiment of the disclosure, the method further comprises: after peeling off the package defining wall, forming a first inorganic encapsulation layer on a side of the organic encapsulation layer away from the substrate.

According to an embodiment of the disclosure, the method further comprises: prior to forming the package defining wall, forming a second inorganic encapsulation layer on a side of the light emitting element away from the substrate.

According to an embodiment of the disclosure, a distance from a side surface of the organic encapsulation layer away from the second inorganic encapsulation layer to a side surface of the second inorganic encapsulation layer is not greater than 50 microns.

According to an embodiment of the disclosure, a material for forming the package defining wall comprises resin or polymethyl methacrylate.

Another aspect of the disclosure proposes a method for manufacturing a display device. According an embodiment of the disclosure, the method comprises a step of packaging a display panel by the method according to any one of the foregoing embodiments.

Another embodiment of the disclosure provides a display device, the display device is manufactured by the above method.

The additional aspects and advantages of the disclosure will be set forth in the description below, which would become apparent from the description below, or be appreciated by practicing the present disclosure.

### BRIEF DESCRIPTION OF DRAWINGS

The above and/or additional aspects and advantages of the disclosure will become apparent and readily understood from description of embodiments with reference to the accompanying drawings.

FIG. 1 illustrates a schematic flow chart of a method for packaging a display panel according to an embodiment of the disclosure;

FIG. 2 is a schematic top view of a product for illustrating step S200 of a packaging method according to an embodiment of the disclosure;

FIGS. 3a-3c are schematic sectional views of a product for illustrating steps S200, S300 and S400 in a packaging method according to an embodiment of the disclosure;

FIGS. 4a-4c are schematic sectional views of a product for illustrating steps S200, S300 and S400 in a packaging method according to another embodiment of the disclosure;

FIGS. 5a-5e are schematic sectional views of a product for illustrating steps S500, S200, S300, S400 and S600 in a packaging method according to yet another embodiment of the disclosure.

### DETAILED DESCRIPTION OF EMBODIMENTS

Embodiments of the present disclosure will be described in detail below, and those skilled in the art will understand that the following embodiments are intended to illustrate the disclosure and should not be construed as limitation to the disclosure. Unless specifically stated otherwise, in the following embodiments, where detailed techniques or conditions are not explicitly described, those skilled in the art may implement the embodiments with reference to common techniques or conditions in the art or according to product specifications.

Inventors of the application are aware that, in order to protect a light emitting element in a display panel, various inorganic or organic materials may be applied to the packaging process of the display panel to prevent the light emitting element of the display panel from being eroded by water or oxygen. In particular, inorganic materials may achieve a better effect of blocking water or oxygen, and organic materials may function to perform stress release, planarization, etc. However, the inventors have realized that, during the process of forming an encapsulation layer with an organic material, since the organic material has a strong fluidity due to a low viscosity, an edge overflow problem is likely to occur when an organic material layer is being formed. This may cause the boundary of the formed organic layer to extend a long distance (e.g., greater than 300 microns) from the light emitting element, resulting in the organic layer having a small thickness, which would degrade the effect of blocking water or oxygen. In addition, the frame width of the display panel will also be increased.

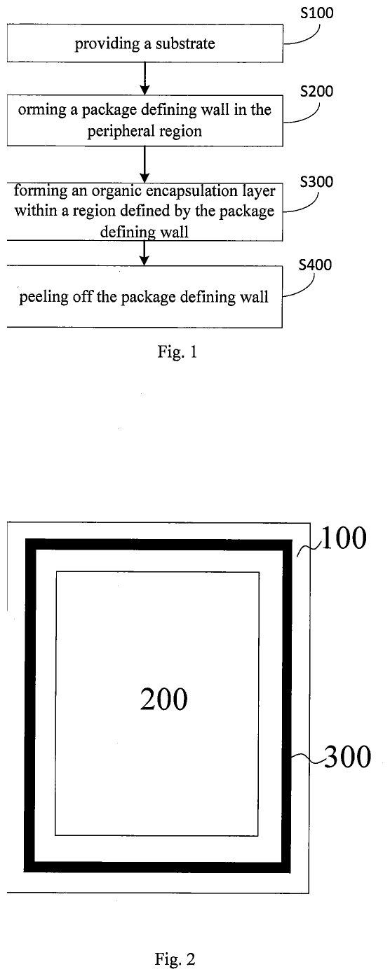

In an aspect of the disclosure, a method for packaging a display panel is proposed. According to an embodiment of the disclosure, referring to FIG. 1, the packaging method comprises the following steps.

S100: providing a substrate. In this step, a substrate 100 is provided, on which a display region A and a peripheral region B are defined. The peripheral region B surrounds the display region A, and a light emitting element 200 is disposed within the display region A.

According to an embodiment of the disclosure, the specific type of the light emitting element 200 is not particularly limited, which may specifically be, for example, an OLED element or the like. Those skilled in the art may select other types of light emitting elements according to requirements for the display panel, which will not be described herein.

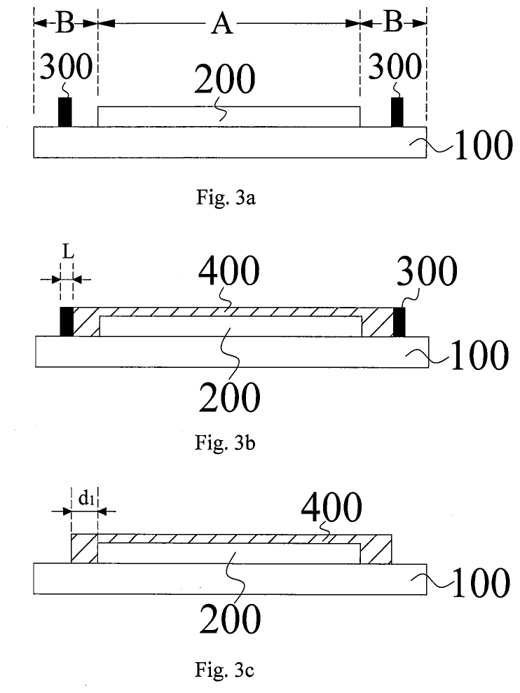

S200: forming a package defining wall within the peripheral region. In this step, a package defining wall 300 is formed within the peripheral region B, the package defining wall 300 is disposed around the display region A and has a gap with the display region A, thus facilitating a subsequent step of forming an organic encapsulation layer in the gap and on the surface of the light emitting element 200. A top view and a sectional view of the product obtained in this step are illustrated in FIG. 2 and FIG. 3a, respectively.

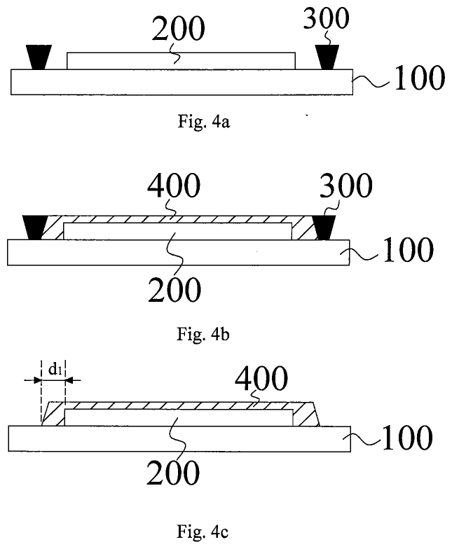

According to an embodiment of the disclosure, a cross section of the package defining wall 300 in a direction perpendicular to the substrate 100 may have a shape of a square or a trapezoid, so that the boundary of a subsequently formed organic encapsulation layer 400 is more flat, thereby improving the package effect of the organic encapsulation layer. It is to be noted that “square” herein specifically includes a quadrate and a rectangle, and “trapezoid” specifically includes a regular trapezoid and an inverted trapezoid. In some embodiments of the disclosure, the cross section of the package defining wall 300 in a direction perpendicular to the substrate 100 may be in a shape of an inverted trapezoid, as shown in FIG. 4a. As a result, a flat boundary of the subsequently formed organic encapsulation layer 400 is obtained, without causing a climbing problem, and the package defining wall 300 having the inverted trapezoidal section can be peeled off more easily.

According to an embodiment of the disclosure, the specific material for the package defining wall 300 is not particularly limited, which may be a peelable protective film material or a micro-mucosal material commonly used in the art, for example, a thermal foaming separation material, including but not limited to materials such as resins, polymethyl methacrylate, and the like. Those skilled in the art can make appropriate selection based on the specific organic material for forming the organic encapsulation layer. According to an embodiment of the disclosure, the method for forming the package defining wall 300 is also not particularly limited, and the package defining wall may be formed by, for example, inkjet printing (IJP), coating, or the like. Those skilled in the art can select appropriate process according to the specific material for forming the packaging defining wall 300.

According to an embodiment of the disclosure, the width of the package defining wall 300 is not particularly limited as long as the package defining wall 300 can effectively limit the flowing range of the organic material. Those skilled in the art can make appropriate adjustment to the width according to the specific material of the package defining wall 300. In some embodiments of the disclosure, referring to FIG. 3b, the width L of the package defining wall 300 may be 10 to 100 microns, so that the boundary of the formed organic layer 400 is flat while the flowing range of the organic material is being limited. According to an embodiment of the disclosure, the thickness of the package defining wall 300 is not less than the thickness of the organic encapsulation layer 400, for example, the thickness of the package defining wall 300 is greater than the thickness of the organic encapsulation layer 400, etc. Those skilled in the art can make appropriate adjustment according to the process of forming the organic encapsulation layer.

In some embodiments of the disclosure, after step S100 and prior to step S200, the method may further comprise a step S500: forming a second inorganic encapsulation layer on a side of the light emitting element away from the substrate.

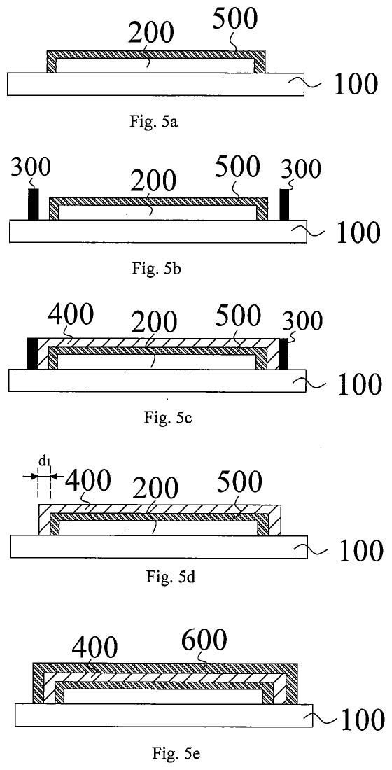

In this step, a second inorganic encapsulation layer 500 may be formed first on a side of the light emitting element 200 away from the substrate 100, and the second inorganic encapsulation layer 500 covers the light emitting element 200, in this way, a thin film encapsulation structure having a stacked structure of inorganics/organics or inorganics/organics/inorganics can be formed subsequently. A schematic sectional view of the product obtained in this step may refer to FIG. 5a.

According to an embodiment of the disclosure, the material of the second inorganic encapsulation layer 500 is not particularly limited, and examples of the material of the second inorganic encapsulation layer 500 include materials capable of blocking water and oxygen such as SiNₓ, SiO₂, SiC, Al₂O₃, ZnS, ZnO, etc. Those skilled in the art can make appropriate selection according to the specific type of the light-emitting element and an actual environment where the display panel operates. According to an embodiment of the disclosure, the method for forming the second inorganic encapsulation layer 500 is not particularly limited, which may specifically comprise, for example, chemical vapor deposition (CVD), sputtering, or atomic layer deposition (ALD), etc. Those skilled in the art can select appropriate process according to the specific material of the second inorganic encapsulation layer 500.

S300: forming an organic encapsulation layer inside the package defining wall.

In this step, an organic encapsulation layer 400 is formed within the area defined by the package defining wall 300, and the organic encapsulation layer 400 covers the light emitting element 200 and the gap between the display region and the package defining wall. In this way, the flowing range of the organic material for the organic encapsulation layer 400 can be limited, which avoids or mitigates the edge overflow problem of the organic encapsulation layer 400. It is to be noted that the phrases like “X covers Y” herein means that an orthographic projection of the object X on the substrate 100 completely covers an orthographic projection of the object Y on the substrate 100.

According to an embodiment of the disclosure, the specific material of the organic encapsulation layer 400 is not particularly limited, which may be an organic encapsulation material commonly used in the art, and may specifically be, for example, a material such as resins, polymethyl methacrylate, or the like. Those skilled in the art can select appropriate materials according to the package requirements for the display panel. According to an embodiment of the disclosure, a method for forming the organic encapsulation layer 400 is also not particularly limited, and the organic encapsulation layer 400 may specifically be formed by, for example, inkjet printing (IJP) and curing. Those skilled in the art can select appropriate process according to the specific material for forming the organic encapsulation layer 400. According to an embodiment of the disclosure, the specific thickness of the organic encapsulation layer 400 is not particularly limited as long as the maximum thickness thereof does not exceed the thickness of the package defining wall 300. Those skilled in the art can make appropriate adjustment according to the size of the light emitting element 200 and the actual package effect, and details are not described herein.

In some embodiments of the disclosure, referring to FIG. 3b, by means of the boundary limiting function of the package defining wall 300, the organic encapsulation layer 400 is directly formed on a surface of the light emitting element 200 away from the substrate 100, thereby obtaining a package of a stacked inorganics/organics structure.

In other embodiments of the disclosure, referring to FIG. 5b, by means of the boundary limiting function of the package defining wall 300, the organic encapsulation layer 400 is directly formed on a surface of the second inorganic encapsulation layer 500 away from the substrate 100, thereby obtaining a package of a stacked organics/inorganics or inorganics/organics/inorganics structure.

S400: peeling off the package defining wall.

In this step, the package defining wall 300 outside the organic encapsulation layer 400 formed in step S300 is peeled off, thus the organic encapsulation layer 400 having a good boundary shape can be obtained. According to an embodiment of the disclosure, the specific process for peeling is not particularly limited as long as the process does not affect the package effect and the performance of the display panel. In some embodiments of the disclosure, a thermal peeling process may be employed, and the temperature during thermal peeling process is not higher than 100 degrees Celsius. In this way, the heated package defining wall 300 may lose adhesion ability and thus can be peeled off, and it may be detached by cleaning, inverting or vibrating the substrate.

In some embodiments of the disclosure, referring to FIG. 3c, after the peeling process, a distance d₁ from a side surface of the organic encapsulation layer 400 away from the light emitting element 200 to a side surface of the light emitting element 200 may be as low as 50 microns, this is beneficial to achieve an effect of an narrow frame. In other embodiments of the disclosure, referring to FIG. 4c, after the peeling process, a maximum distance d₁ from a side surface of the organic encapsulation layer 400 away from the light emitting element 200 to a side surface of the light emitting element 200 may be as low as 50 microns, which is more conducive to achieving the effect of a narrow frame. In other embodiments of the disclosure, referring to FIG. 5d, after the peeling process, a distance from a side surface of the organic encapsulation layer 400 away from the second inorganic encapsulation layer 500 to a side surface of the second inorganic encapsulation layer 500 may be as low as 50 microns, which is not only helpful to producing a display panel with better package effect, but also is conducive to realization of a narrow frame for the display panel. In some embodiments, the gap between the package defining wall and the display region has a width of not more than 50 microns in a horizontal direction.

In some examples of the disclosure, after step S400, the method further comprises step S600: forming a first inorganic encapsulation layer on a side of the organic encapsulation layer away from the substrate. In this step, a first inorganic encapsulation layer 600 is formed on a side of the organic encapsulation layer 400 away from the substrate 100.

According to an embodiment of the disclosure, the specific material of the first inorganic encapsulation layer 600 is not particularly limited, including but not limited to materials capable of blocking water and oxygen, such as SiNₓ, SiO₂, SiC, Al₂O₃, ZnS, ZnO, etc. Those skilled in the art may select appropriate materials according to the specific type of the light-emitting element and an actual environment where the display panel operates. According to an embodiment of the disclosure, a specific process of forming the first inorganic encapsulation layer 600 is not particularly limited, which may specifically comprise, for example, chemical vapor deposition (CVD), sputtering, atomic layer deposition (ALD), or the like. Those skilled in the art can select appropriate process according to the specific material of the first inorganic encapsulation layer 600. According to an embodiment of the disclosure, the specific thickness of the first inorganic encapsulation layer 600 is not particularly limited, which may specifically be, for example, 0.05 to 2.5 microns, etc. Those skilled in the art can make appropriate adjustment according to the actual package effect of the display panel, and details are not described here.

In summary, according to an embodiment of the disclosure, a packaging method is proposed, in which a package defining wall is formed in advance prior to forming an organic encapsulation layer so as to limit the flowing range of the organic material, thereby effectively mitigating the overflow problem of the package organic layer. Moreover, the package defining wall can be peeled off after the organic encapsulation layer is formed, so that the width of the frame of the display panel will not be increased.

In another aspect of the disclosure, a method for manufacturing a display device is proposed. The method according to an embodiment of the disclosure comprises a step of packaging a display panel using the packaging method described above.

In addition to the step of packaging a display panel, the manufacturing method further comprises other necessary steps, such as a step of forming a light emitting element, and the like. Those skilled in the art can make appropriate design according to the specific constitution of the display device, which would not be described herein.

In summary, according to an embodiment of the disclosure, a method for manufacturing a display device is disclosed, which may solve the problem that the organic material is likely to overflow during the process of packaging a light-emitting element, thereby obtaining a display device with better package effect, without increasing the frame width of the resulted display device. Those skilled in the art can understand that the features and advantages described previously for the packaging method of a display panel hold for the method for manufacturing a display device, which would not be described again.

In a further aspect of the disclosure, a display device is proposed. According to an embodiment of the disclosure, the display device is manufactured by means of the above method for manufacturing a display device.

According to an embodiment of the disclosure, the specific type of the display device is not particularly limited, which may specifically be, for example, an OLED display device or the like. Those skilled in the art can make appropriate design according to the specific type of the light emitting element, and details of the display device would not be described here.

It is to be noted that, in addition to the display panel, the display device may further comprise other necessary components and structures. Taking an OLED display device as an example, it specifically comprises, for example, a cover plate, a housing, a control circuit board, a power line, or the like. The skilled in the art may design the display device according to the requirements on the display device.

In summary, according to an embodiment of the disclosure, a display device is proposed, in which the light emitting element can be better packaged, so that the display device has a longer service life. Those skilled in the art can understand that the features and advantages described previously for the method for manufacturing a display device also hold for the display device, which would not be described here again.

In the description of the disclosure, orientations or positional relationships indicated by the terms “center”, “longitudinal”, “transverse”, “length”, “width”, “thickness”, “upper”, “lower”, “front”, “rear”, “left”, “right”, “vertical”, “horizontal”, “top”, “bottom”, “inside”, “outside”, “clockwise”, “counterclockwise”, “axial”, “radial”, “circumferential” and the like are based on the orientations or positional relationships shown in the drawings, which are merely intended to facilitate and simplify describing the embodiments, rather than indicating or implying that the related device or element must have a particular orientation, or must be constructed and operated in a particular orientation, and thus are not to be construed as limiting the disclosure.

Moreover, the terms “first” and “second” are used for descriptive purposes only and are not to be construed as indicating or implying a relative importance or implicitly indicating the number of technical features indicated. Thus, a feature defined with “first” and “second” may mean at least one such feature exist, either explicitly or implicitly. In the description of the disclosure, the meaning of “a plurality” is at least two, such as two, three, etc., unless specifically defined otherwise.

In the description, statements with reference to the terms “an to embodiment”, “some embodiments”, “example”, “specific example”, “some examples”, or the like indicates that specific features, structures, materials, or characteristics described in conjunction with the embodiment or example are included in at least one embodiment or example of the disclosure. In the description, usage of the above terms is not necessarily directed to the same embodiment or example. Furthermore, the specific features, structures, materials, or characteristics described may be combined in a suitable manner in any one or more embodiments or examples. In addition, various embodiments or examples described in the specification, as well as features of various embodiments or examples, may be combined by those skilled in the art without any conflict.

While embodiments of the disclosure have been shown and described above, it can be understood that the foregoing embodiments are illustrative and are not to be construed as limiting the scope of the present application. Variations, amendments, substitutions and modifications may be made by those skilled in the art to the embodiments without departing the scope of the disclosure.

1. A method for packaging a display panel, comprising:
providing a substrate, the substrate comprising a display region and a peripheral region surrounding the display region in a plan view, the display region comprising a light emitting element;
forming a package defining wall in the peripheral region, the package defining wall surrounding the display region in a plan view, wherein a gap separates the package defining wall from the display region;
forming an organic encapsulation layer within a region defined by the package defining wall, the organic encapsulation layer covering overlapping the light emitting element and the gap; and
peeling off the package defining wall.

2. The method according to claim 1, wherein a cross section of the package defining wall in a direction perpendicular to the substrate is in a shape of a square or a trapezoid.

3. The method according to claim 1, wherein a distance from, a side surface of the organic encapsulation layer away from the light emitting element to a side surface of the light emitting element is not greater than 50 microns.

4. The method according to claim 1, wherein a width of the package defining wall in a horizontal direction is in a range from 10 microns to 100 microns.

5. The method according to claim 1,
wherein the package defining wall is peeled off by a thermal peeling process, and
wherein a temperature during the thermal peeling process is not higher than 100 degrees Celsius.

6. The method according to claim 1, wherein the method further comprises:
after peeling off the package defining wall, forming a first inorganic encapsulation layer on a side of the organic encapsulation layer away from the substrate.

7. The method according to claim 1, wherein the method further comprises:
prior to forming the package defining wall, forming a second inorganic encapsulation layer on a side of the light emitting element away from the substrate.

8. The method according to claim 7, wherein a distance from a side surface of the organic encapsulation layer away from the second inorganic encapsulation layer to a side surface of the second inorganic encapsulation layer is not greater than 50 microns.

9. The method according to claim 1, wherein a material for forming the package defining wall comprises resin or polymethyl methacrylate.

10. A method for manufacturing a display device, comprising packaging the display panel by the method for packaging the display panel according to claim 1.

11. A display, the display manufactured by the method for manufacturing the display device according to claim 10.
